(19) United States
(12) Patent Application Publication
(10) Pub. No.: US 2018/0053698 A1
(43) Pub. Date: Feb. 22, 2018

(54) SYSTEM AND METHOD FOR CHARACTERIZING CRITICAL PARAMETERS RESULTING FROM A SEMICONDUCTOR DEVICE FABRICATION PROCESS

(71) Applicant: FREESCALE SEMICONDUCTOR, INC., Austin, TX (US)

(72) Inventors: Paige M. Holm, Phoenix, AZ (US); Lianjun Liu, Chandler, AZ (US)

(21) Appl. No.: 15/240,701

(22) Filed: Aug. 18, 2016

(51) Int. Cl. H01L 21/66; B81C 99/00; G01R 27/02

(52) U.S. Cl. CPC H01L 22/30; G01R 27/02; B81C 99/0065; H01L 22/20

(57) ABSTRACT

A system includes three related structures. A first structure includes a first finger interposed between a first pair of sidewalls. The first finger has a first length and a first width, and is separated from each of the sidewalls by a first gap having a first spacing. A second structure includes a second finger interposed between a second pair of sidewalls. The second finger has a second length and the first width, and is separated from each of the sidewalls by a second gap having a second spacing. A third structure includes a third finger interposed between a third pair of sidewalls. The third finger has the second length and a second width, and is separated from each of the sidewalls by a third gap having a second spacing. Resistance and capacitance measurements of the three structures are used to extract critical parameters resulting from a semiconductor device fabrication process.

### TECHNICAL FIELD OF THE INVENTION

The present invention relates generally to semiconductor device fabrication processes. More specifically, the present invention relates to a system and method for characterizing critical parameters of a device manufactured in accordance with a semiconductor device fabrication process.

### BACKGROUND OF THE INVENTION

Microelectromechanical systems (MEMS) technology provides a way to make very small mechanical structures and integrate these structures with electrical devices on a single substrate using conventional batch semiconductor processing techniques. One common application of MEMS is the design and manufacture of sensor devices. MEMS sensor devices are widely used in applications such as automotive, inertial guidance systems, household appliances, game devices, protection systems for a variety of devices, and many other industrial, scientific, and engineering systems.

Conventional MEMS fabrication processes typically employ a slab (i.e., structural layer) of semiconductor material of a given resistivity and thickness into which features are etched to form electromechanical structures that perform the desired functions needed to realize MEMS devices, such as accelerometers and gyroscopes. The critical device parameters include, for example, the electrical resistivity of the structural layer, the thickness of the structural layer, and the width of the etched features in which the width is determined by the original mask pattern dimension and the amount of undercut incurred during the etch process. All three of these key critical parameters (i.e., resistivity, thickness, and amount of undercut) typically vary slightly across a wafer, wafer to wafer, and/or process lot to process lot. Due to these variations, it may be necessary to routinely monitor these critical parameters in order to optimize production yields, device performance, and quality of the MEMS devices.

Some prior art techniques electrically measure the sheet resistance of the MEMS structural layer by using conventional van der Pauw patterns or Kelvined resistor structures. However, to determine the local resistivity of the structural layer, the layer thickness and/or the lateral geometries of the structures must be accurately known. Because the lateral dimensions (and their variations of interest) of typical MEMS features is on the order of a micron or less, it is not typically feasible to use optical microscopy. Accordingly, more complex Scanning Electron Microscopy (SEM) inspections are needed to obtain the lateral physical dimensions. Furthermore, in order to obtain the local structural layer thickness uniformity information, a wafer must be sacrificed for cross section and multiple measurements are thereafter performed along this cross section. Thus, it is not practically and cost effectively feasible to routinely map wafers with this approach. Nor does it provide data from the actual product wafers where such date would be of greatest value.

Other prior art techniques utilize capacitance measurement on some type of dynamically driven, oscillating or resonance MEMS structures. Capacitance measurements on these movable structures involve complex, sophisticated testing techniques and may involve comparison to numerical analysis and simulations. Further, these techniques are primarily focused on extracting the lateral dimensions of a MEMS features (more specifically, amount of etch undercut) and assume that the thickness of the structural layer is known. In actually, the thickness of the structural layer and the gap (which includes etch undercut) are coupled together in the capacitance measurement.

### BRIEF DESCRIPTION OF THE DRAWINGS

The accompanying figures in which like reference numerals refer to identical or functionally similar elements throughout the separate views, the figures are not necessarily drawn to scale, and which together with the detailed description below are incorporated in and form part of the specification, serve to further illustrate various embodiments and to explain various principles and advantages all in accordance with the present invention.

FIG. 1 shows a generalized top view of a process control monitoring system in accordance with an embodiment;

FIG. 2 shows a simplified top view of a wafer structure that includes a plurality of semiconductor devices and at least one process control monitoring system of FIG. 1;

FIG. 3 shows a top view of the process control monitoring system of FIG. 1 depicting the resistance and capacitances used to determine the critical device parameters;

FIG. 4 shows a cross-sectional side view of one of the structures of the process control monitoring system along section lines 4-4 of FIG. 3;

FIG. 5 shows a top view of an example layout of one of the structures of the process control monitoring system; and

FIG. 6 shows a flowchart of a critical parameter characterization process in accordance with another embodiment.

### DETAILED DESCRIPTION

In overview, embodiments disclosed herein entail a process control monitoring system and a method for characterizing critical device parameters resulting from a semiconductor device fabrication process, where the semiconductor device fabrication process is utilized to form the process control monitoring system as well as a plurality of semiconductor devices in a structural layer of the substrate. The process control monitoring system includes three related structures, but with different critical dimensions. The general configuration of each of the three structures includes a single fixed “finger” of a given width and length etched into a structural layer of a given thickness. On each side of the finger, there is a given spacing to adjacent sidewalls of the structural layer. Various electrical contacts are made to the finger and to the adjacent sidewalls of the structural layer in order to obtain a resistance measurement of the finger and to measure a static, differential capacitance between the finger and the surrounding sidewalls. The resistance and capacitance measurements enable electrical characterization of, for example, a product wafer, in order to extract the critical device parameters of the electrical resistivity of the structural layer, the thickness of the structural layer, and the amount of undercut of the etched features. The system and associated methodology enables the extraction of these critical device parameters without the need for sacrificial wafers, cross sectioning, or the use of complex SEM analysis. Accordingly, variations in resistivity, material thickness, and amount of undercut can be readily monitored in order to optimize production yields, device performance, and the quality of semiconductor devices, such as microelectromechanical systems (MEMS) devices.

The instant disclosure is provided to further explain in an enabling fashion the best modes, at the time of the application, of making and using various embodiments in accordance with the present invention. The disclosure is further offered to enhance an understanding and appreciation for the inventive principles and advantages thereof, rather than to limit in any manner the invention. The invention is defined solely by the appended claims including any amendments made during the pendency of this application and all equivalents of those claims as issued.

It should be understood that the use of relational terms, if any, such as first and second, top and bottom, and the like are used solely to distinguish one from another entity or action without necessarily requiring or implying any actual such relationship or order between such entities or actions. Furthermore, some of the figures may be illustrated using various shading and/or hatching to distinguish the different elements produced within the various structural layers. These different elements within the structural layers may be produced utilizing current and upcoming microfabrication techniques of depositing, patterning, etching, and so forth. Accordingly, although different shading and/or hatching is utilized in the illustrations, the different elements within the structural layers may be formed out of the same material.

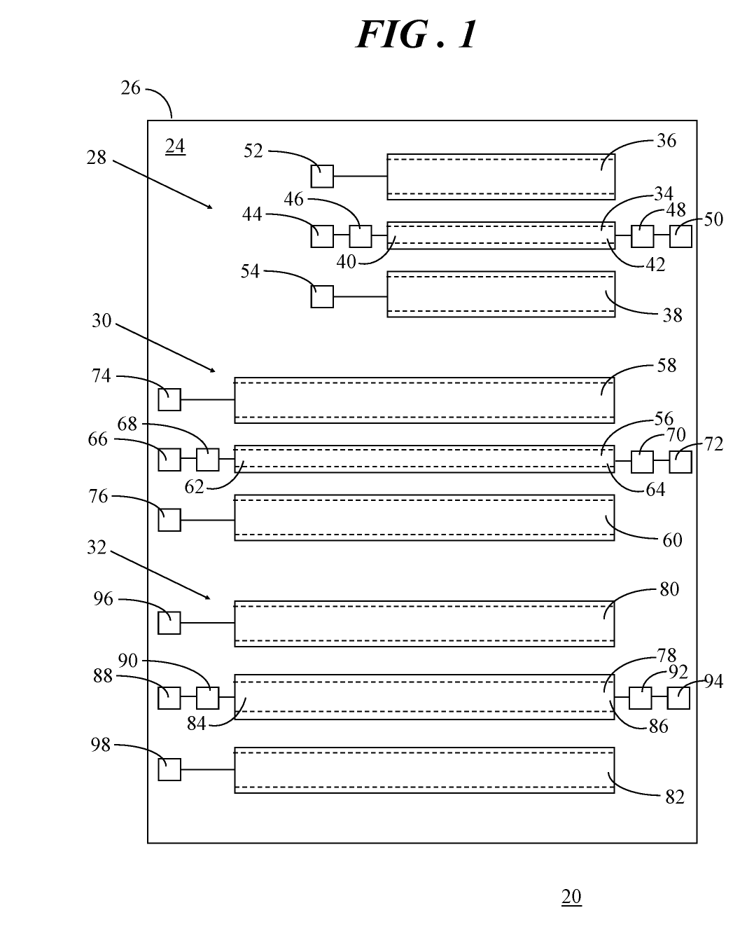

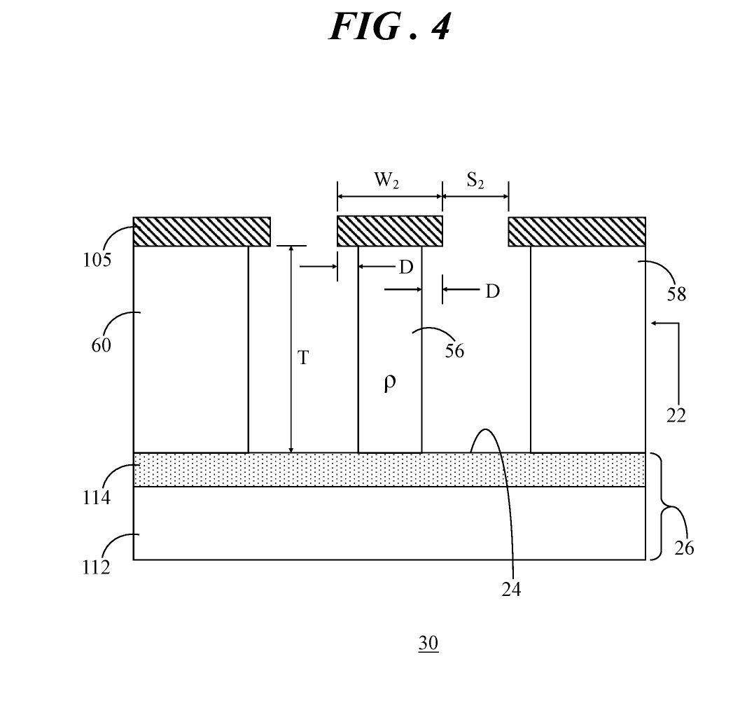

Referring to FIG. 1, FIG. 1 shows a generalized top view of a process control monitoring system 20 in accordance with an embodiment. Process control monitoring system 20 is generally formed in a structural layer 22 (shown in the side view of FIG. 4) on a surface 24 of a substrate 26. Process control monitoring system 20 generally includes a first structure 28, a second structure 30, and a third structure 32 formed in structural layer 22.

First structure 28 includes a first finger 34 interposed between a first pair of sidewalls 36, 38. First finger 34 has a first end 40 and a second end 42. A first pair of terminals 44, 46 is in electrical communication with first end 40 of first finger 34, and a second pair of terminals 48, 50 is in electrical communication with second end 42. In addition, a first contact 52 is in electrical communication with sidewall 36 and a second contact 54 is in electrical communication with sidewall 38. The term “electrical communication” refers to an electrical connection via, for example, conductive traces, bond wires, or any other technique implemented to provide electrical continuity between respective terminals or contacts and their respective structures.

Similarly, second structure 30 includes a second finger 56 interposed between a second pair of sidewalls 58, 60. Second finger 56 has a first end 62 and a second end 64. A first pair of terminals 66, 68 is in electrical communication with first end 62 of second finger 56, and a second pair of terminals 70, 72 is in electrical communication with second end 64. In addition, a first contact 74 is in electrical communication with sidewall 58 and a second contact 76 is in electrical communication with sidewall 60.

Third structure 32 includes a third finger 78 interposed between a third pair of sidewalls 80, 82. Third finger 78 has a first end 84 and a second end 86. A first pair of terminals 88, 90 is in electrical communication with first end 84 of third finger 78, and a second pair of terminals 92, 94 is in electrical communication with second end 86. In addition, a first contact 96 is in electrical communication with sidewall 80 and a second contact 98 is in electrical communication with sidewall 82.

First finger 34 is immovable relative to its corresponding first pair of sidewalls 36, 38. Likewise, second finger 56 is immovable relative to its corresponding second pair of sidewalls 58, 60. And, third finger 78 is immovable relative to its corresponding third pair of sidewalls 80, 82. That is first, second, and third fingers 34, 56, 78 and sidewalls 36, 38, 58, 60, 80, 82 are all fixedly (i.e., non-movably) coupled to surface 24 of substrate 26.

As will be discussed in significantly greater detail below, the resistance of each of first, second, and third fingers 34, 56, 78 and the static capacitance between each of first, second, and third fingers 34, 56, 78 and its immediate surroundings can be measured. The resistance and capacitance measurements for each of first, second, and third, structures 28, 30, 32 having differing critical dimensions can be utilized to determine critical device parameters (e.g., resistivity, thickness of the structural layer, and amount of undercut of the etched features) resulting from the particular semiconductor fabrication process implemented to form them.

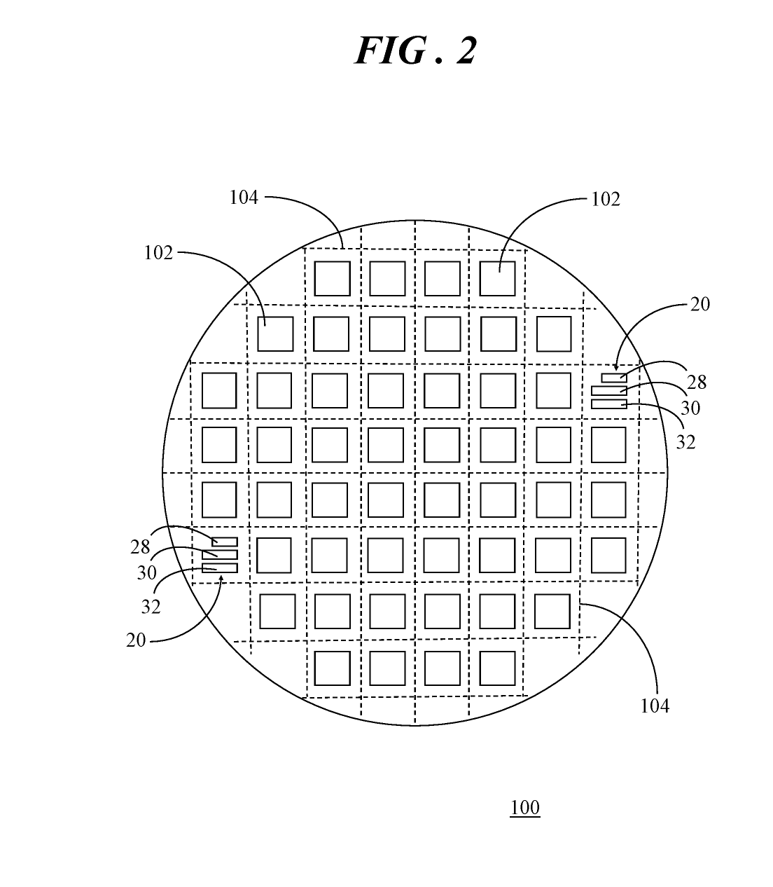

Referring now to FIG. 2, FIG. 2 shows a simplified top view of a wafer structure 100 that includes a plurality of semiconductor devices 102 and at least one process control monitoring system 20. Wafer structure 100 is shown with a number of semiconductor devices 102 formed therein that are separated by scribe lines 104, where each semiconductor device 102 may include a MEMS or MEMS-like structure having a semiconductor layer (e.g., structural layer 22 of FIG. 4) and narrow features etched into structural layer 22. Semiconductor devices 102 are represented by boxes for simplicity of illustration. However, those skilled in the art will recognize that each of semiconductor devices 102 can include a plurality of movable and non-movable features. In accordance with an embodiment, semiconductor devices 102 and first, second, and third structures 28, 30, 32 of process control monitoring system 20 are concurrently fabricated using the same semiconductor device fabrication process. Accordingly, the critical device parameters extracted utilizing process control monitoring system 20 and methodology described below will apply equivalently to the features of semiconductor devices 102.

In this example, two process control monitoring systems 20 are shown. However, wafer structure 100 can include any suitable quantity of process control monitoring systems 20 distributed across wafer structure 100. Further, the two process control monitoring systems 20 are also shown in areas of wafer structure 100 that are fully surrounded by scribe lines 104. However, process control monitoring systems 20 can be formed at any suitable unused portion of wafer structure 100 since following characterization of the critical parameters and subsequent dicing of wafer structure 100 along scribe lines 104, they will no longer be used.

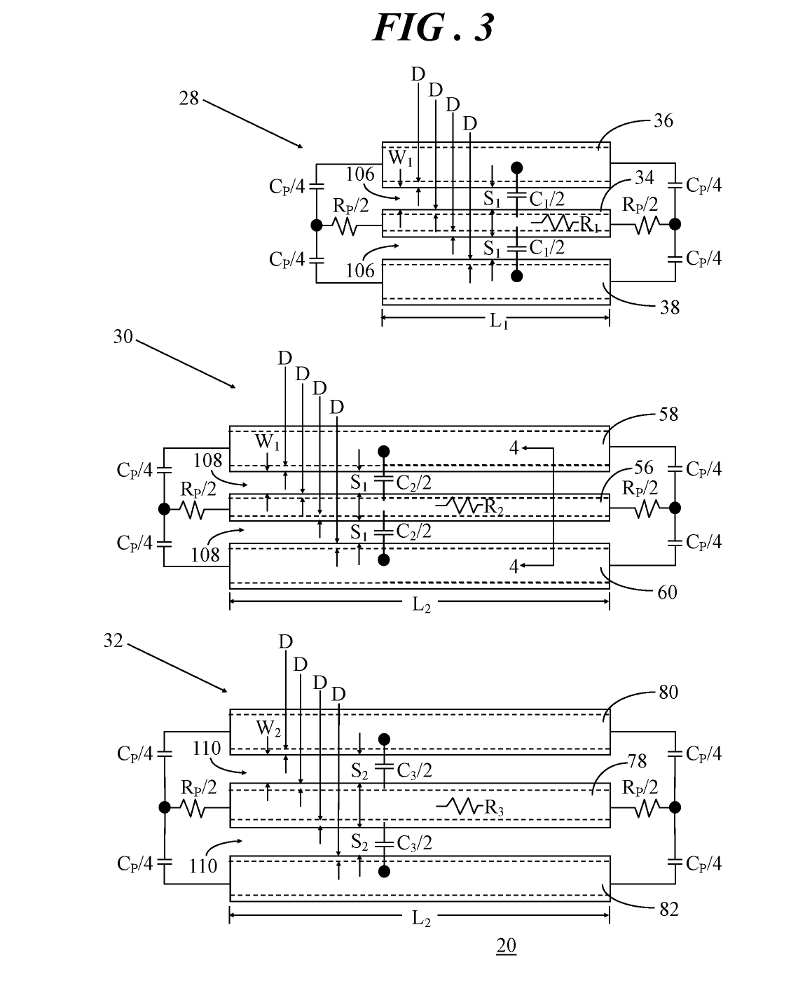

Referring to FIGS. 3 and 4, FIG. 3 shows a top view of the process control monitoring system 20 depicting the resistance and capacitances used to determine the critical device parameters of material resistivity, layer thickness, and amount of undercut of the etched features and FIG. 4 shows a cross-sectional side view of second structure 30 of process control monitoring system 20 along section lines 4-4 of FIG. 3. That is, FIGS. 3 and 4 show generalized sketches of first, second, and third structures 28, 30, 32 that are labeled with the parameters used in the analysis. An algorithm described below, which may be realized as program code executed by a computing system (not shown), is used to extract the critical device parameters from simple resistance and capacitance measurements on the static (i.e., non-movable) structures 28, 30, 32.

In the sketches provided in FIGS. 3 and 4, L is the printed finger length and W is the printed finger width as determined by the original pattern dimension of an etch mask 105, where each of the length and width is parallel to surface 24 of substrate 26 (FIG. 1). First finger 34 is separated from each of sidewalls 36, 38 by a gap 106 having a dimension or width referred to herein as a spacing, S. Likewise, second finger 56 is separated from each of sidewalls 58, 60 by a gap 108 having a spacing, S, and third finger 78 is separated from each of sidewalls 80, 82 by a gap 110 having a spacing, S.

First finger 34 exhibits a first length, L₁, and a first width, W₁. Additionally, first finger 34 is separated from each of the adjacent sidewalls 36, 38 by a first spacing, S₁. Second finger 56 exhibits a second length, L₂, and first width, W₁. Additionally, second finger 56 is separated from each of the adjacent sidewalls 58, 60 by first spacing, S₁. Third finger 78 exhibits second length, L₂, and a second width, W₂. Additionally, third finger 78 is separated from each of the adjacent sidewalls 80, 82 by a second spacing, S₂. In an embodiment, first length, L₁, differs from second length, L₂, first width, W₁, differs from second width, W₂, and first spacing, S₁, differs from second spacing, S₂.

As exemplified in FIG. 4, a substrate structure may be a silicon on insulator (SOI) wafer that includes a handle substrate 112, a buried oxide layer 114, and a semiconductor layer, referred to herein as structural layer 22. The features of semiconductor devices 102 (FIG. 3) and process control monitoring system 20 are formed in structural layer 22. Thus, each of first, second, and third fingers 34, 56, 78 exhibits a thickness, T, perpendicular to surface 24 of substrate 26 corresponding to the thickness of structural layer 22, where the thickness, T, is generally equivalent for each of the first, second, and third fingers 34, 56, 78.

With continued reference to FIGS. 3 and 4, the process variables (i.e., critical device parameters) to be monitored utilizing first, second, and third structures 28, 30, 32 include an amount of undercut of the etched features, referred to herein as an etch undercut parameter, D, the resistivity parameter, ρ, of structural layer 22, and the thickness parameter, T, of structural layer 22. R₁, R₂, R₃ are the measured resistances and C₁, C₂, C₃ are the measured capacitances of first, second, and third structures 28, 30, 32, respectively. Thus, R₁, R₂, R₃, C₁, C₂, C₃ are known since they can be directly measured. R_{P} and C_{P} are the parasitic resistance and capacitance, respectively, of first, second, and third structures 28, 30, and 32.

R₁ and C₁ can be characterized by the following equations:

$$\begin{matrix}{R}_{1} = \frac{ρ {L}_{1}}{( {W}_{1} - 2 D ) T} + {R}_{P} & ( 1 ) \\ {C}_{1} = \frac{2 ɛ {L}_{1} T}{( {S}_{1} + 2 D )} + {C}_{P} & ( 2 )\end{matrix}$$

Similarly, R₂ and C₂ can be characterized by the following equations:

$$\begin{matrix}{R}_{2} = \frac{ρ {L}_{2}}{( {W}_{1} - 2 D ) T} + {R}_{P} & ( 3 ) \\ {C}_{2} = \frac{2 ɛ {L}_{2} T}{( {S}_{1} + 2 D )} + {C}_{P} & ( 4 )\end{matrix}$$

And, R₃ and C₃ can be characterized by the following equations:

$$\begin{matrix}{R}_{3} = \frac{ρ {L}_{2}}{( {W}_{2} - 2 D ) T} + {R}_{P} & ( 5 ) \\ {C}_{3} = \frac{2 ɛ {L}_{2} T}{( {S}_{2} + 2 D )} + {C}_{P} & ( 6 )\end{matrix}$$

The system of equations (1), (2), (3), (4), (5), and (6) can be solved by first subtracting pairs of equations to eliminate the measurement parasitics (i.e., R_{P} and C_{P}). The parasitics can be eliminated from the length variation structures as follows:

$$\begin{matrix}( {R}_{1} - {R}_{2} ) = \frac{ρ ( {L}_{1} - {L}_{2} )}{( {W}_{1} - 2 D ) T} & ( 7 ) \\ ( {C}_{1} - {C}_{2} ) = \frac{2 ɛ T ( {L}_{1} - {L}_{2} )}{( {S}_{1} + 2 D )} & ( 8 )\end{matrix}$$

Then the parasitics can be eliminated from the width variation structures as follows:

$$\begin{matrix}( {R}_{2} - {R}_{3} ) = \frac{ρ {L}_{2}}{T} [ \frac{1}{( {W}_{1} - 2 D )} - \frac{1}{( {W}_{2} - 2 D )} ] & ( 9 ) \\ ( {C}_{2} - {C}_{3} ) = 2 ɛ {L}_{2} T [ \frac{1}{( {S}_{1} + 2 D )} - \frac{1}{( {S}_{2} + 2 D )} ] & ( 10 )\end{matrix}$$

The RC products of equations (7) and (8) eliminates the thickness parameter, T, as follows:

$$( {R}_{1} - {R}_{2} ) ( {C}_{1} - {C}_{2} ) = \frac{2 {ɛρ ( {L}_{1} + {L}_{2} )}^{2}}{( {W}_{1} - 2 D ) ( {S}_{1} + 2 D )} \qquad ( 11 )$$

Solving equation (11) for the resistivity parameter, ρ, yields an equation (12) in the last remaining variable, i.e., the etch undercut parameter, D, which can be used to solve for resistivity parameter, ρ, after etch undercut parameter, D is determined.

$$ρ = \frac{( {R}_{1} - {R}_{2} ) ( {C}_{1} - {C}_{2} ) ( {W}_{1} - 2 D ) ( {S}_{1} + 2 D )}{2 {ɛ ( {L}_{1} - {L}_{2} )}^{2}} \qquad ( 12 )$$

To solve for the etch undercut parameter, D, the RC product of equations (9) and (10) is determined to again eliminate the thickness parameter, T, as follows:

$$( {R}_{2} - {R}_{3} ) ( {C}_{2} - {C}_{3} ) = 2 ɛρ {L}_{2}^{2} [ \frac{1}{( {W}_{1} - 2 D )} - \frac{1}{( {W}_{2} - 2 D )} ] [ \frac{1}{( {S}_{1} + 2 D )} - \frac{1}{( {S}_{2} + 2 D )} ] \qquad ( 13 )$$

Now substituting for the resistivity parameter, ρ, from equation (12) yields the following:

$$( {R}_{2} - {R}_{3} ) ( {C}_{2} - {C}_{3} ) = \frac{( {R}_{1} - {R}_{2} ) ( {C}_{1} - {C}_{2} ) ( {w}_{1} - 2 D ) ( {s}_{1} + 2 D ) {L}_{2}^{2}}{{( {L}_{1} - {L}_{2} )}^{2}} [ \frac{1}{( {W}_{1} - 2 D )} - \frac{1}{( {W}_{2} - 2 D )} ] [ \frac{1}{( {S}_{1} + 2 D )} - \frac{1}{( {S}_{2} + 2 D )} ] \qquad ( 14 )$$

Distributing the two numerator factors containing, etch undercut parameter, D, into the two bracketed terms gives:

$$( {R}_{2} - {R}_{3} ) ( {C}_{2} - {C}_{3} ) = \frac{( {R}_{1} - {R}_{2} ) ( {C}_{1} - {C}_{2} ) {L}_{2}^{2}}{{( {L}_{1} - {L}_{2} )}^{2}} [ 1 - \frac{( {W}_{1} - 2 D )}{( {W}_{2} - 2 D )} ] [ 1 - \frac{( {S}_{1} + 2 D )}{( {S}_{2} + 2 D )} ] \qquad ( 15 )$$

Note that the form of equation (15) implies that if either of the two widths or the two spacings are identical (i.e., W₁=W₂ or S₁=S₂) then the analysis becomes invalid. Continuing the numerical analysis:

$$\begin{matrix}\frac{( {R}_{2} - {R}_{3} ) ( {C}_{2} - {C}_{3} ) {( {L}_{1} - {L}_{2} )}^{2}}{( {R}_{1} - {R}_{2} ) ( {C}_{1} - {C}_{2} ) {L}_{2}^{2}} = [ 1 - \frac{( {W}_{1} - 2 D )}{( {W}_{2} - 2 D )} ] [ 1 - \frac{( {S}_{1} + 2 D )}{( {S}_{2} + 2 D )} ] & ( 16 ) \\ \frac{( {R}_{2} - {R}_{3} ) ( {C}_{2} - {C}_{3} ) {( {L}_{1} - {L}_{2} )}^{2}}{( {R}_{1} - {R}_{2} ) ( {C}_{1} - {C}_{2} ) {L}_{2}^{2}} = [ \frac{( {W}_{2} - 2 D ) - ( {W}_{1} - 2 D )}{( {W}_{2} - 2 D )} ] [ \frac{( {S}_{2} + 2 D ) - ( {S}_{1} + 2 D )}{( {S}_{2} + 2 D )} ] & ( 17 )\end{matrix}$$

And continuing the expansion:

$$\begin{matrix}\frac{( {R}_{2} - {R}_{3} ) ( {C}_{2} - {C}_{3} ) {( {L}_{1} - {L}_{2} )}^{2}}{( {R}_{1} - {R}_{2} ) ( {C}_{1} - {C}_{2} ) {L}_{2}^{2}} = [ \frac{( {W}_{2} - {W}_{1} )}{( {W}_{2} - 2 D )} ] [ \frac{( {S}_{2} - {S}_{1} )}{( {S}_{2} + 2 D )} ] & ( 18 ) \\ \frac{( {R}_{2} - {R}_{3} ) ( {C}_{2} - {C}_{3} ) {( {L}_{1} - {L}_{2} )}^{2}}{( {R}_{1} - {R}_{2} ) ( {C}_{1} - {C}_{2} ) {L}_{2}^{2}} = [ \frac{( {W}_{2} - {W}_{1} ) ( {S}_{2} - {S}_{1} )}{( {W}_{2} - 2 D ) ( {S}_{2} + 2 D )} ] & ( 19 ) \\ \frac{( {R}_{2} - {R}_{3} ) ( {C}_{2} - {C}_{3} ) {( {L}_{1} - {L}_{2} )}^{2}}{( {R}_{1} - {R}_{2} ) ( {C}_{1} - {C}_{2} ) {L}_{2}^{2}} = [ \frac{( {W}_{2} - {W}_{1} ) ( {S}_{2} - {S}_{1} )}{- 4 {D}^{2} + ( 2 {W}_{2} - 2 {S}_{2} ) D + {W}_{2} {S}_{2}} ] & ( 20 )\end{matrix}$$

Now rearranging and putting into standard quadratic form:

$$\begin{matrix}- 4 {D}^{2} + ( 2 {W}_{2} - 2 {S}_{2} ) D + {W}_{2} {S}_{2} = \frac{( {R}_{1} - {R}_{2} ) ( {C}_{1} - {C}_{2} ) {L}_{2}^{2} ( {W}_{2} - {W}_{1} ) ( {S}_{2} - {S}_{1} )}{( {R}_{2} - {R}_{3} ) ( {C}_{2} - {C}_{3} ) {( {L}_{1} - {L}_{2} )}^{2}} & ( 21 ) \\ 4 {D}^{2} + ( 2 {S}_{2} - 2 {W}_{2} ) D + \frac{( {R}_{1} - {R}_{2} ) ( {C}_{1} - {C}_{2} ) {L}_{2}^{2} ( {W}_{2} - {W}_{1} ) ( {S}_{2} - {S}_{1} )}{( {R}_{2} - {R}_{3} ) ( {C}_{2} - {C}_{3} ) {( {L}_{1} - {L}_{2} )}^{2}} - {W}_{2} {S}_{2} = 0 & ( 22 )\end{matrix}$$

In some embodiments, the width, W, and the spacing, S, are equivalent. That is, the first width is equivalent to the first spacing (W₁=S₁X₁) and the second width is equivalent to the second spacing (W₂=S₂X₂), but W₁ is different from W₂ and S₁ is different from S₂ amongst first, second, and third structures 28, 30, 32 (i.e., X₁≠X₂). In such a configuration, some simplification can be leveraged, as follows:

$$\begin{matrix}4 {D}^{2} + [ \frac{( {R}_{1} - {R}_{2} ) ( {C}_{1} - {C}_{2} ) {L}_{2}^{2} ( {X}_{2} - {X}_{1} )}{( {R}_{2} - {R}_{3} ) ( {C}_{2} - {C}_{3} ) {( {L}_{1} - {L}_{2} )}^{2}} - {X}_{2}^{2} ] = 0 & ( 23 ) \\ D = \frac{1}{2} \sqrt{{X}_{2}^{2} - \frac{( {R}_{1} - {R}_{2} ) ( {C}_{1} - {C}_{2} ) {{L}_{2}^{2} ( {X}_{2} - {X}_{1} )}^{2}}{( {R}_{2} - {R}_{3} ) ( {C}_{2} - {C}_{3} ) {( {L}_{1} - {L}_{2} )}^{2}}} & ( 24 )\end{matrix}$$

Once the etch undercut parameter, D, has been computed from either of equations (22) or (24), then the resistivity parameter, ρ, can be determined from equation (12), and the thickness parameter, T, can be determined from either of equations (7), (8), (9), or (10). Most accurately, however, the thickness parameter, T, can be determined from equation (8), as follows:

$$T = \frac{( {C}_{1} - {C}_{2} ) ( {S}_{1} + 2 D )}{2 ɛ ( {L}_{1} - {L}_{2} )} \qquad ( 25 )$$

As demonstrated above, the judiciously selected first and second lengths, first and second widths, and first and second widths for associated ones of first, second, and third fingers 34, 56, 78 are utilized to determine the critical device parameters. That is, the construct of first, second, and third structures 28, 30, 32 together with the analysis routines form a self-consistent method of extracting the three key physical device parameters of MEMS structural layer resistivity parameter (p), thickness parameter (T), and etch undercut parameter (D) directly from the electrical resistance and capacitance measurements.

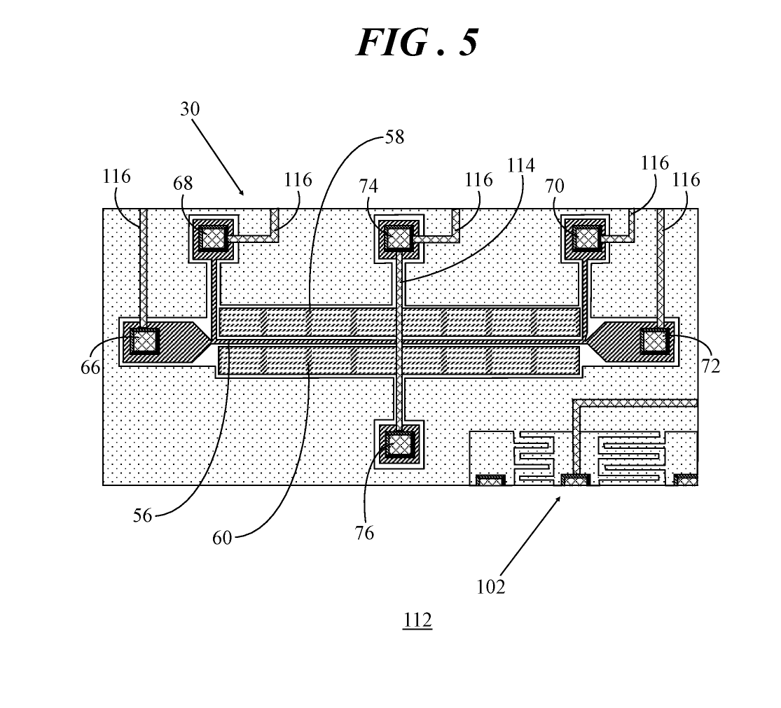

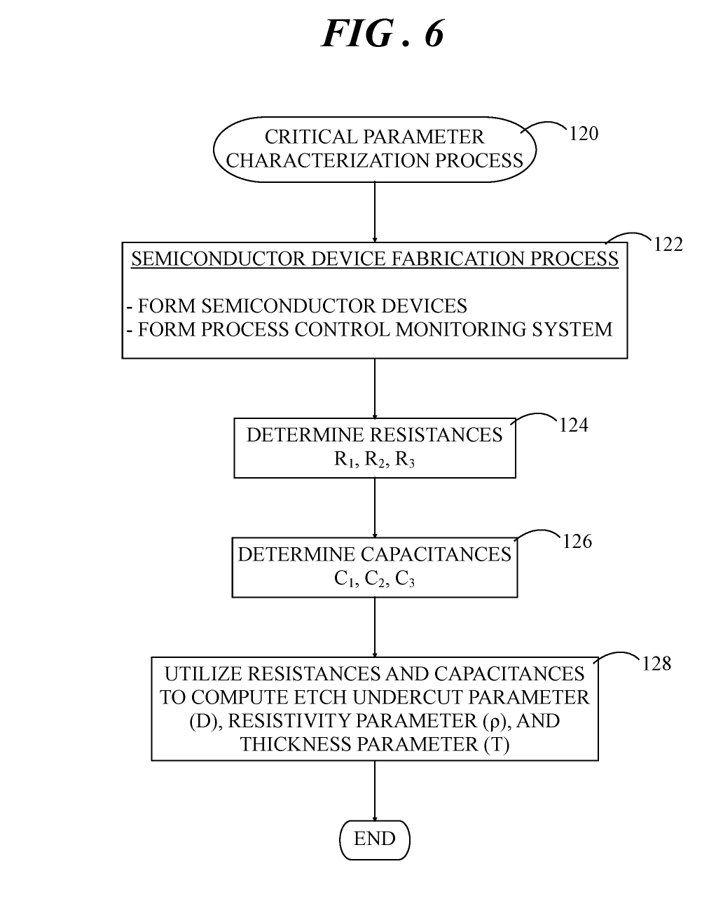

FIG. 5 shows a top view of an example layout 112 of one of the structures of the process control monitoring system 20 (FIG. 1). In this example, layout 112 includes second structure 30 having second finger 56 interposed between second pair of sidewalls 58, 60. Further, first pair of terminals 66, 68, second pair of terminals 70, 72 connected with second finger 56, and first and second contacts 74, 76 connected with second pair of sidewalls 58, 60 (as described above) are also illustrated in example layout 112. An electrically conductive trace 114 interconnects first and second contacts 74, 76, and various electrically conductive input/output (I/O) traces 116 are used to connect first pair of terminals 66, 68, second pair of terminals 70, 72, first contact 74, and second contact 76 to measurement equipment (generally discussed below in connection with FIG. 6). Layout 112 additionally shows a portion of one of semiconductor devices 102 which may include a combination of movable and nonmovable features (e.g., a comb structure with movable mass) and electrical connections.

A stippled pattern over much of structural layer 22 indicates a dielectric material overlying the structural features formed within structural layer 22 to yield a buried semiconductor layer. However, the stippled pattern is not shown over second structure 30 for clarity of illustration. It should be understood that the dielectric material may also be disposed between conductive traces 114, 116 and the underlying structural layer 22 to provide suitable electrical isolation between various features.

FIG. 6 shows a flowchart of a critical parameter characterization process 120 in accordance with another embodiment. Critical process characterization process 120 may be implemented in connection with any wafer processing technology (i.e., semiconductor device fabrication process) for which a quantitative assessment of the critical device parameters of resistivity, structural layer thickness, and etch undercut parameters are desired.

At a block 122, a semiconductor fabrication process that includes operations of, for example, patterning, deposition, and etching is implemented to form wafer structure 100 (FIG. 2) that includes semiconductor devices 102 (FIG. 2) and process control monitoring system 20 (FIG. 1) in structural layer 22 (FIG. 4).

At a block 124, resistances R₁, R₂, R₃ of corresponding first, second, and third fingers 34, 56, 78 are determined. By way of example, R₁, R₂, R₃ may be measured utilizing a four-terminal resistance measurement device (e.g., ohmmeter) capable of performing four-lead Kelvin sensing. Referring briefly to first structure 28 shown in FIG. 1, current may be supplied to first finger 34 via terminals 44, 50 (i.e., the current leads). The resulting voltage can be measured between terminals 46, 48 (i.e., voltage leads) and the resistance can be extracted via Ohm's Law, V=IR. The separation of current and voltage leads eliminates the lead and contact resistance from the measurement, which is advantageous for precise measurement of low resistance values. Alternative embodiments may employ a different resistance measurement technique for determining R₁, R₂, R₃.

At a block 126, static capacitances C₁, C₂, C₃ of corresponding first, second, and third structures 28, 30, 32 (FIG. 1) are determined. By way of example, C₁, C₂, C₃ may be measured by utilizing a capacitance measurement device (e.g., an LCR meter). Again referring to first structure 28 shown in FIG. 1, first and second contacts 52, 54 may be connected to the capacitance measurement device at a first potential (HIGH) and first pair of terminals 44, 46 and second pair of terminals 48, 50 may be connected to the capacitance measurement device at a second potential (LOW). First structure 28 is thereafter subjected to an alternating current (AC) voltage source. An LCR meter measures the voltage across and the current through first structure 28. From the ratio of the voltage and current, the LCR meter can determine the magnitude of the impedance. The phase angle between the voltage and current is also measured. The LCR meter can calculate the capacitance from the impedance and the phase angle. Alternative embodiments may employ a different capacitance measurement technique for determining C₁, C₂, C₃.

At a block 128 the measured resistances, R₁, R₂, R₃, and the measured capacitances, C₁, C₂, C₃, are utilized to compute etch undercut parameter, D, resistivity parameter, ρ, and thickness parameter, T, as discussed in detail above. Again, a computing system executing an algorithm containing the above equations may be utilized to compute etch undercut parameter, resistivity parameter, and thickness parameter. These computed critical parameters can be utilized in order optimize production yields, device performance, and quality of the semiconductor devices. Thereafter, critical parameter characterization process ends.

Embodiments are described above with a single “finger” per each of the structures (e.g., first structure 28 having first finger 34, second structure 30 having second finger 56, and third structure 32 having third finger 78 as shown in FIG. 1) for compactness and simplicity. Alternative embodiments may include multiple “fingers” per structure to yield higher measures capacitance values and lower measured resistance values.

Thus, a process control monitoring system and a method of characterizing critical parameters resulting from a semiconductor device fabrication process are discloses herein. An embodiment of a process control monitoring system formed on a substrate comprises a first structure formed in a structural layer of the substrate, the first structure including a first finger interposed between a first pair of sidewalls, the first finger exhibiting a first length and a first width, each of which is parallel to a surface of the substrate, and the first finger being separated from each of the first pair of sidewalls by a first gap having a first spacing. The process control monitoring system further comprises a second structure formed in the structural layer of the substrate, the second structure including a second finger interposed between a second pair of sidewalls, the second finger exhibiting a second length and the first width, each of which is parallel to the surface of the substrate, and the second finger being separated from each of the second pair of sidewalls by a second gap having the first spacing. And the system process control monitoring comprises a third structure formed in the structural layer of the substrate, the third structure including a third finger interposed between a third pair of sidewalls, the third finger exhibiting the second length and a second width, each of which is parallel to the surface of the substrate, and the third finger being separated from each of the third pair of sidewalls by a third gap having a second spacing.

An embodiment of a method of characterizing critical parameters resulting from a semiconductor device fabrication process comprises implementing the semiconductor device fabrication process to form a process control monitoring system in a structural layer of a substrate. The process control monitoring system includes a first structure including a first finger interposed between a first pair of sidewalls, the first finger exhibiting a first length and a first width, each of which is parallel to a surface of the substrate, and the first finger being separated from each of the first pair of sidewalls by a first gap having a first spacing. The process control monitoring system further includes a second structure including a second finger interposed between a second pair of sidewalls, the second finger exhibiting a second length and the first width, each of which is parallel to the surface of the substrate, and the second finger being separated from each of the second pair of sidewalls by a second gap having the first spacing. And, the process control monitoring system further includes a third structure including a third finger interposed between a third pair of sidewalls, the third finger exhibiting the second length and a second width, each of which is parallel to the surface of the substrate, and the third finger being separated from each of the third pair of sidewalls by a third gap having a second spacing. The method further comprises determining the critical parameters based on the first and second lengths, the first and second widths, and the first and second spacings for associated ones of the first, second, and third fingers.

An embodiment of a wafer structure comprises a substrate, a plurality of semiconductor devices formed in a structural layer of the substrate, and a process control monitoring system formed in a structural layer of the substrate, wherein the plurality of semiconductor devices and the process control monitoring system are fabricated concurrently using the same semiconductor device fabrication process. The process control monitoring system includes a first structure including a first finger interposed between a first pair of sidewalls, the first finger exhibiting a first length and a first width, each of which is parallel to a surface of the substrate, and the first finger being separated from each of the first pair of sidewalls by a first gap having a first spacing. The process control monitoring system further includes a second structure including a second finger interposed between a second pair of sidewalls, the second finger exhibiting a second length and the first width, each of which is parallel to the surface of the substrate, and the second finger being separated from each of the second pair of sidewalls by a second gap having the first spacing. And the process control monitoring system further includes a third structure including a third finger interposed between a third pair of sidewalls, the third finger exhibiting the second length and a second width, each of which is parallel to the surface of the substrate, and the third finger being separated from each of the third pair of sidewalls by a third gap having a second spacing. The first and second lengths, the first and second widths, and the first and second spacings for associated ones of the first, second, and third fingers are utilized to determine critical parameters of the plurality of the semiconductor devices resulting from the semiconductor device fabrication process.

The embodiments described herein enable the extraction of critical device parameters with a self-consistent analysis of the resistance and capacitance measurements on the structures in which these critical parameters are coupled. Further, these critical parameters are effectively decoupled by the simultaneous solution of coupled equations describing the resistance and capacitance measurements on the different structures. Accordingly, the resistance and capacitance measurements enable electrical characterization of, for example, a product wafer, in order to extract the critical device parameters of the electrical resistivity of the structural layer, the thickness of the structural layer, and the amount of undercut of the etched features. The system and associated methodology enables the extraction of these critical device parameters without the need for sacrificial wafers, cross sectioning, or the use of complex SEM analysis. Accordingly, variations in resistivity, material thickness, and amount of undercut can be readily monitored in order to optimize production yields, device performance, and the quality of semiconductor devices, such as microelectromechanical systems (MEMS) devices.

This disclosure is intended to explain how to fashion and use various embodiments in accordance with the invention rather than to limit the true, intended, and fair scope and spirit thereof. The foregoing description is not intended to be exhaustive or to limit the invention to the precise form disclosed. Modifications or variations are possible in light of the above teachings. The embodiment(s) was chosen and described to provide the best illustration of the principles of the invention and its practical application, and to enable one of ordinary skill in the art to utilize the invention in various embodiments and with various modifications as are suited to the particular use contemplated. All such modifications and variations are within the scope of the invention as determined by the appended claims, as may be amended during the pendency of this application for patent, and all equivalents thereof, when interpreted in accordance with the breadth to which they are fairly, legally, and equitably entitled.

1. A process control monitoring system formed on a substrate comprising:
a first structure formed in a structural layer of said substrate, said first structure including a first finger interposed between a first pair of sidewalls, said first finger exhibiting a first length and a first width, each of which is parallel to a surface of said substrate, and said first finger being separated from each of said first pair of sidewalls by a first gap having a first spacing;
a second structure formed in said structural layer of said substrate, said second structure including a second finger interposed between a second pair of sidewalls, said second finger exhibiting a second length and said first width, each of which is parallel to said surface of said substrate, and said second finger being separated from each of said second pair of sidewalls by a second gap having said first spacing; and
a third structure formed in said structural layer of said substrate, said third structure including a third finger interposed between a third pair of sidewalls, said third finger exhibiting said second length and a second width, each of which is parallel to said surface of said substrate, and said third finger being separated from each of said third pair of sidewalls by a third gap having a second spacing.

2. The process control monitoring system of claim 1 wherein:
said first length differs from said second length;
said first width differs from said second width; and
said first spacing differs from said second spacing.

3. The process control monitoring system of claim 2 wherein:
said first width is equivalent to said first spacing; and
said second width is equivalent to said second spacing.

4. The process control monitoring system of claim 1 wherein each of said first, second, and third fingers exhibits a thickness perpendicular to said surface of said substrate, said thickness being equivalent for said each of said first, second, and third fingers.

5. The process control monitoring system of claim 1 wherein said first, second, and third fingers are immovable relative to corresponding said first, second, and third pairs of sidewalls.

6. The process control monitoring system of claim 1 wherein:
each of said first, second, and third fingers includes a first end and a second end; and
for said each of said first, second, and third fingers, said process control monitoring system further comprises a first pair of terminals in electrical communication with said first end and a second pair of terminals in electrical communication with said second end, said first and second pair of terminals being configured for connection with a four terminal resistance measurement device to determine a resistance of said each of said first, second, and third fingers.

7. The process control monitoring system of claim 6 wherein:
each of said first, second, and third pairs of sidewalls includes a first sidewall and a second sidewall; and
for said each of said first, second, and third pairs of sidewalls, said process control monitoring system further comprises a first contact and a second contact, said first contact being in electrical communication with said first sidewall, and said second contact being in electrical communication with said second sidewall, wherein said first and second electrical contacts are configured for connection with a capacitance measurement device at a first potential and said first and second pairs of terminals are further configured for connection with said capacitance measurement device at a second potential for determining a capacitance between said each of said first, second, and third fingers and associated said each of said first, second, and third pairs of sidewalls.

8. The process control monitoring system of claim 1 wherein said first and second lengths, said first and second widths, and said first and second spacings for associated ones of said first, second, and third fingers are utilized to determine an etch undercut parameter of said first, second, and third fingers.

9. The process control monitoring system of claim 1 wherein said first and second lengths, said first and second widths, and said first and second spacings for associated ones of said first, second, and third fingers are utilized to determine a resistivity parameter of said substrate.

10. The process control monitoring system of claim 1 wherein said first and second lengths, said first and second widths, and said first and second spacings for associated ones of said first, second, and third fingers are utilized to determine a thickness parameter of said structural layer perpendicular to said surface of said substrate.

11. A wafer structure including the process control monitoring system of claim 1, wherein said wafer structure further comprises a plurality of semiconductor devices formed in said structural layer, said process control monitoring system and said plurality of semiconductor devices being fabricated concurrently using the same semiconductor device fabrication process.

12. A method of characterizing critical parameters resulting from a semiconductor device fabrication process comprising:
implementing said semiconductor device fabrication process to form a process control monitoring system in a structural layer of a substrate, said process control monitoring system including:
a first structure including a first finger interposed between a first pair of sidewalls, said first finger exhibiting a first length and a first width, each of which is parallel to a surface of said substrate, and said first finger being separated from each of said first pair of sidewalls by a first gap having a first spacing;
a second structure including a second finger interposed between a second pair of sidewalls, said second finger exhibiting a second length and said first width, each of which is parallel to said surface of said substrate, and said second finger being separated from each of said second pair of sidewalls by a second gap having said first spacing; and
a third structure including a third finger interposed between a third pair of sidewalls, said third finger exhibiting said second length and a second width, each of which is parallel to said surface of said substrate, and said third finger being separated from each of said third pair of sidewalls by a third gap having a second spacing; and
determining said critical parameters based on said first and second lengths, said first and second widths, and said first and second spacings for associated ones of said first, second, and third fingers.

13. The method of claim 12 wherein said implementing operation forms said process control monitoring system to have said first, second, third fingers that are immovable relative to corresponding said first, second, and third pairs of sidewalls.

14. The method of claim 12 wherein said determining comprises:
determining a first resistance of said first finger;
determining a first capacitance between said first pair of sidewalls and said first finger;
determining a second resistance of said second finger;
determining a second capacitance between said second pair of sidewalls and second first finger;
determining a third resistance of said third finger;
determining a third capacitance between said third pair of sidewalls and third first finger; and
computing said critical parameters based on said first, second, and third resistances and said first, second, and third capacitances.

15. The method of claim 14 wherein said determining each of said first, second, and third resistances comprises measuring a Kelvin resistance of said each of said first, second, and third fingers.

16. The method of claim 14 wherein said computing operation comprises:
computing an etch undercut parameter;
computing a resistivity parameter of said substrate; and
computing a thickness parameter of said structural layer perpendicular to said surface of said substrate, said etch undercut parameter, said resistivity parameter, and said thickness parameter being said critical parameters, and each of said etch undercut parameter, said resistivity parameter, and said thickness parameter being computed utilizing said first, second, and third resistances and said first, second, and third capacitances.

17. The method of claim 12 further comprising implementing said semiconductor device fabrication process to produce a wafer structure that includes said process control monitoring system and a plurality of semiconductor devices in said structural layer, wherein said critical parameters determined utilizing said first, second, and third structures of said process control monitoring system characterizes said critical parameters of said plurality of said semiconductor devices.

18. A wafer structure comprising:
a substrate;
a plurality of semiconductor devices formed in a structural layer of said substrate; and
a process control monitoring system formed in a structural layer of said substrate, wherein said plurality of semiconductor devices and said process control monitoring system are fabricated concurrently using the same semiconductor device fabrication process, said process control monitoring system including:
a first structure including a first finger interposed between a first pair of sidewalls, said first finger exhibiting a first length and a first width, each of which is parallel to a surface of said substrate, and said first finger being separated from each of said first pair of sidewalls by a first gap having a first spacing;
a second structure including a second finger interposed between a second pair of sidewalls, said second finger exhibiting a second length and said first width, each of which is parallel to said surface of said substrate, and said second finger being separated from each of said second pair of sidewalls by a second gap having said first spacing; and
a third structure including a third finger interposed between a third pair of sidewalls, said third finger exhibiting said second length and a second width, each of which is parallel to said surface of said substrate, and said third finger being separated from each of said third pair of sidewalls by a third gap having a second spacing, wherein said first and second lengths, said first and second widths, and said first and second spacings for associated ones of said first, second, and third fingers are utilized to determine critical parameters of said plurality of said semiconductor devices resulting from said semiconductor device fabrication process.

19. The wafer structure of claim 18 wherein:
said first length differs from said second length;
said first width differs from said second width; and
said first spacing differs from said second spacing.

20. The wafer structure of claim 18 wherein said first, second, and third fingers are immovable relative to corresponding ones of said first, second, and third pairs of sidewalls.
